(19) United States
(12) Patent Application Publication
(10) Pub. No.: US 2025/0379050 A1
(43) Pub. Date: Dec. 11, 2025

(54) PATTERN REPLICATION TECHNIQUES FOR CONDUCTIVE INTERCONNECTS USING SELECTIVE DEPOSITION

(71) Applicant: Intel Corporation, Santa Clara, CA (US)

(72) Inventors: Abhishek A. Sharma, Portland, OR (US); Wilfred Gomes, Portland, OR (US); Anand S. Murthy, Portland, OR (US); Tahir Ghani, Portland, OR (US)

(73) Assignee: Intel Corporation, Santa Clara, CA (US)

(21) Appl. No.: 18/736,821

(22) Filed: Jun. 7, 2024

(51) Int. Cl. H01L 21/02; H01L 21/768

(52) U.S. Cl. CPC H01L 21/02636; H01L 21/76811; H01L 21/76831; H01L 21/76897

(57) ABSTRACT

Integrated circuit (IC) structures with conductive interconnects may be fabricated with pattern replication techniques using selective deposition. In one example, a method involves providing a preliminary IC structure with a conductive interconnect including a first conductive material, recessing an insulator material from around the conductive interconnect to expose a top and sides of the conductive interconnect. A thin conformal layer of an insulator material may be deposited over the exposed top and sides of the first conductive material. A further material (e.g., a conductive material) may then be selectively deposited over the first conductive material. An insulator material may be provided over and around the selectively deposited material, and then the further material may be removed to expose the first conductive material. The method may then involve providing a second conductive material over the first conductive material.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional side view of an IC structure including conductive interconnects fabricated with pattern replication techniques using selective deposition, in accordance with various embodiments.

FIG. 2 is a flow diagram of an example method for fabricating an IC structure with pattern replication techniques using selective deposition, in accordance with some embodiments.

FIGS. 3-4, 5A-5B, 6A-6B, 7A-7B, 8A-8B, and 9A-9B provide cross-sectional side views at various stages in the fabrication of an example IC structure according to the method of FIG. 2, in accordance with some embodiments.

FIG. 10 illustrates a cross-sectional side view of another example IC structure fabricated with pattern replication techniques using selective deposition, in accordance with various embodiments.

FIG. 11 is a top view of a wafer and dies that may include any of the IC devices disclosed herein, in accordance with any of the embodiments disclosed herein.

FIG. 12 is a side, cross-sectional view of an IC package that may include any of the IC devices disclosed herein, in accordance with various embodiments.

FIG. 13 is a side, cross-sectional view of an IC device assembly that may include any of the IC devices disclosed herein, in accordance with any of the embodiments disclosed herein.

FIG. 14 is a block diagram of an example electrical device that may include any of the IC devices disclosed herein, in accordance with any of the embodiments disclosed herein.

### DETAILED DESCRIPTION

Disclosed herein are integrated circuit (IC) structures including conductive interconnects fabricated with pattern replication techniques using selective deposition, in accordance with various embodiments. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

IC fabrication usually includes two stages. The first stage of IC fabrication is typically referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to provide connection between individual components. The BEOL usually starts with forming the first metal layer on the wafer. The first metal layer is often called M0. More metal layers can be formed on top of M0, and these metal layers are often called M1, M2, and so on.

Fabricating conductive interconnects with smaller widths and pitches to accommodate the ongoing drive towards higher density and higher capacity devices can pose many challenges. For example, conductive interconnects having a high aspect ratio (e.g., interconnects having a greater height or depth than width) may have a significantly tapered shape. Excessively tapered interconnects may result in degraded system performance, and can even be the source of defective devices (e.g., due to misalignment between a conductive contact with an excessively tapered interconnect). In some cases, it may be possible to form tall interconnects by stacking multiple vias; however, alignment issues are also a problem when attempting to stack multiple vias.

In contrast, in accordance with examples described herein, conductive interconnects fabricated with pattern replication techniques using selective deposition may be formed with higher aspect ratios without the alignment challenges associated with conventional techniques. In one example, a method involves providing a preliminary IC structure with a conductive interconnect including a first conductive material, recessing an insulator material from around the conductive interconnect to expose a top and sides of the conductive interconnect. A thin conformal layer of an insulator material may be deposited over the exposed top and sides of the first conductive material. A further material (e.g., a conductive material) may then be selectively deposited over the first conductive material. An insulator material may be provided over and around the selectively deposited material, and the further material may be removed to expose the first conductive material. The method may then involve providing a second conductive material over the first conductive material, which may have substantially the same or a different material composition from the first conductive material.

IC structures as described herein, in particular IC structures including conductive interconnects fabricated with pattern replication techniques using selective deposition, in accordance with various embodiments, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including conductive interconnects fabricated with pattern replication techniques using selective deposition, in accordance with various embodiments as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

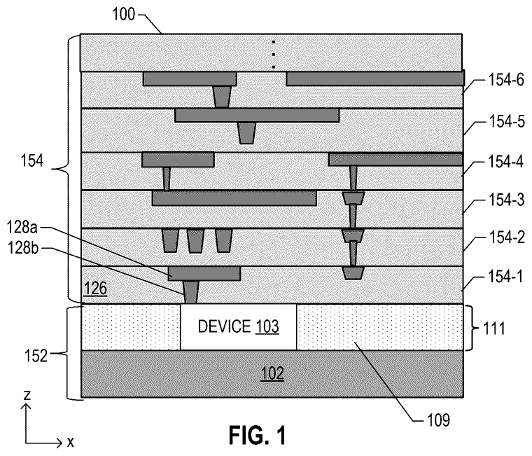

FIG. 1 is a cross-sectional side view of an IC structure including conductive interconnects fabricated with pattern replication techniques using selective deposition, in accordance with various embodiments.

The IC structure 100 includes FEOL layers 152 and back end of line BEOL layers 154. The FEOL layer 152 includes a device region 111 over a substrate 102, where the device region 111 includes devices (of which device 103 is shown). The substrate 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device 103 is an example of a frontend device (e.g., a frontend transistor such as FinFETs, nanowire transistors, nanoribbon transistors, frontend memory cells, or other frontend devices). The device 103 may be considered a “frontend device” due to its location in a FEOL layer. According to examples, the device 103 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 111 may be electrically isolated from one another by any suitable insulator material 109.

The BEOL layers 154 may include a plurality of backend interconnects electrically coupled to (e.g., in electrically conductive contact with at least portions of) one or more of the plurality of FEOL devices of the FEOL layer 152. Various BEOL interconnect layers 154 may be/include one or more metal layers of a metallization stack of the IC device. The IC structure 100 may also include one or more backend devices. A device may be considered a “backend device” due to its location in a BEOL layer. A backend device may be present in lower or higher up interconnect layers in the metallization stack. In one example, a backend device may include a transistor of any architecture, such as any non-planar or planar architecture, or other device.

Various metal layers of the BEOL interconnect layers 154 may be used to interconnect the various inputs and outputs of the devices (e.g., logic devices) in the FEOL layer 152. In one example, each of the BEOL interconnect layers 154 may include vias and lines/trenches. For example, the BEOL interconnect layer 154-1 includes a via portion 128b and a line or trench/interconnect portion 128a. The trench portion 128a of a metal layer is configured for transferring signals and power along electrically conductive (e.g., metal) lines (also sometimes referred to as “trenches”) extending in the x-y plane (e.g., in the x or y directions), while the via portion 128b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 154 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) material 126. The insulating medium may include any suitable ILD materials such as silicon oxide, carbon-doped silicon oxide, silicon carbide, silicon nitride, aluminum oxide, and/or silicon oxynitride. In some embodiments, the dielectric material 126 disposed between the interconnect structures in different ones of the interconnect layers may have different compositions; in other embodiments, the composition of the dielectric material 126 between different interconnect layers may be the same. The example illustrated in FIG. 1 depicts six interconnect layers 154-1, 154-2, 154-3, 154-4, 154-5, and 154-6, however, fewer or more interconnect layers may be present.

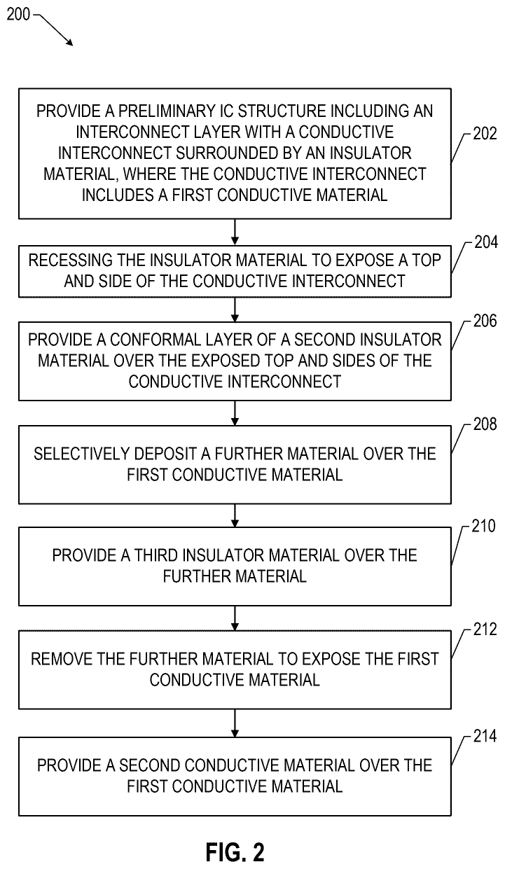

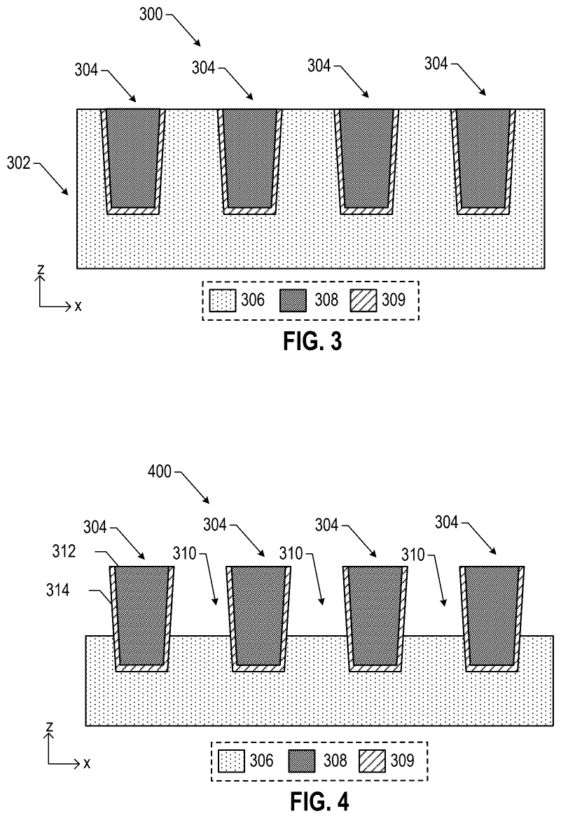

According to examples described herein, the conductive interconnects in one or more metal layers of the metallization stack of an IC device may be formed with pattern replication techniques using selective deposition. FIG. 2 is a flow diagram of an example method 200 for fabricating an IC structure with pattern replication techniques using selective deposition. FIGS. 3-4, 5A-5B, 6A-6B, 7A-7B, 8A-8B, and 9A-9B provide cross-sectional side views at various stages in the fabrication of an example IC structure according to the method of FIG. 2, in accordance with some embodiments. Although the operations of the method of FIG. 2 are illustrated once each and in a particular order, the operations may be performed in any suitable order and repeated as desired. For example, one or more operations may be performed in parallel to fabricate multiple IC structures including devices fabricated with pattern replication techniques using selective deposition substantially simultaneously. In another example, the operations may be performed in a different order to reflect the structure of an IC device in which devices fabricated with pattern replication techniques using selective deposition will be implemented.

In addition, the example fabricating methods of FIG. 2 may include other operations not specifically shown in FIG. 2, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 2 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 2, the method 200 begins with a process 202 of providing a preliminary IC structure including an interconnect layer with a conductive interconnect surrounded by an insulator material, where the conductive interconnect includes a first conductive material. The IC structure 300 of FIG. 3 is an example resulting structure of the process 202. The IC structure 300 includes an interconnect layer 302 (e.g., a BEOL layer) with an insulator material 306 and a plurality of conductive interconnects 304. The insulator material 306 may be any suitable insulator material, such as the ILD 126 discussed above with respect to FIG. 1. The conductive interconnects 304 may be conductive lines or conductive vias. The interconnect layer 302 may represent an interconnect layer that is lower or higher up in the metallization stack. For example, the interconnect layer 302 may be a lower metal layer such as metal 1 layer (M1), a metal 2 layer (M2), a metal 3 layer (M3), metal layer 4 (M4), metal layer 5 (M5), etc. In another example, the interconnect layer 302 may represent a higher up metal layer, such as a metal 6 layer (M6), metal 7 layer (M7), a metal 8 layer (M8), etc. In one example, the interconnect layer may represent a global metal layer (e.g., which may be referred to as global metal layer 0 (GM0), global metal layer 1 (GM1), etc.). Global metal layers may be interconnect layers over the local metal layers M0-MX (where X represents number of a metal layer, and where X may be in a range of about 5-12 or more). In one such example, global metal layers typically have a larger thickness and pitch relative to lower metal layers, and may include, for example, a hybrid bonding layer, a pad layer, etc., in addition to, or instead of, metal lines and vias. Thus, the interconnect layer 302 may be any interconnect layer in a metallization stack that includes conductive interconnects.

The conductive interconnects 304 may be formed with any suitable technique, such as a damascene process (e.g., a single or dual damascene process), and may involve a via first or via last technique. In the example illustrated in FIG. 3, the conductive interconnects include a conductive fill material 308 and a liner 309 on sidewalls of the openings in which the conductive interconnects are formed (e.g., a liner 309 on sidewalls of the conductive interconnects 304). The conductive fill material may include a metal such as copper or another suitable metal (e.g., ruthenium, tungsten, or another metal). The liner 309 may include a material that acts as a diffusion barrier and/or adhesion layer. In some examples, the liner 309 includes tantalum, tantalum and nitrogen (e.g., TaN), titanium, titanium and nitrogen (e.g., TiN), or other suitable barrier and/or adhesion material.

The method 200 continues with the process 204 of recessing the insulator material to expose a top and side of the conductive interconnects. The IC structure 400 of FIG. 4 is an example resulting structures of the process 204. As can be seen in FIG. 4, openings 310 are present between adjacent conductive interconnects 304, and a top surface 312 as well as sides or sidewalls 314 of the conductive interconnects 304 is exposed after recessing the insulator material 306. The extent to which the insulator material 306 is recessed may depend on implementation. For example, if it is desired to form air gaps between adjacent conductive interconnects 304, the insulator material 306 may be recessed more than if air gaps are not going to be formed. In various examples, the insulator material 306 may be recessed to a level so that about 20-100 percent of the height of the sidewalls of the conductive interconnects are exposed after the insulator material 306 is recessed (e.g., where the height of a sidewall is a dimension of the sidewall in a plane substantially orthogonal to the interconnect layer, such as along the z-axis as shown in FIG. 4). As can be seen in FIG. 4, the liner 309 is exposed on the sides of the conductive interconnects 304.

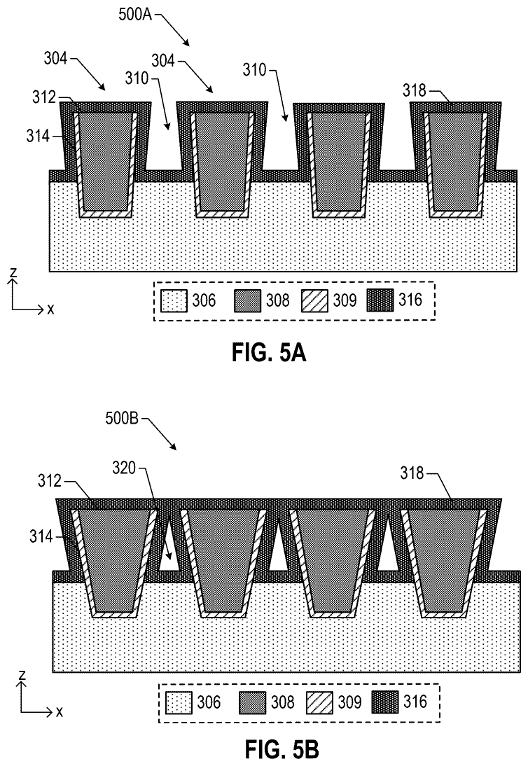

The method 200 continues with the process 206 of providing a conformal layer of a second insulator material over the exposed top and sides of the conductive interconnect. The IC structures 500A and 500B of FIGS. 5A and 5B are example resulting structures of the process 206. As can be seen in FIG. 5A illustrates an example in which air gaps are not to be formed between adjacent conductive interconnects as a result of the process 206. FIG. 5B illustrates an example in which air gaps are to be formed between adjacent conductive interconnects as a result of the process 206. Turning first to FIG. 5A, the IC structure 500A includes a conformal layer 318 of an insulator material 316 over exposed surfaces. Therefore, in the example illustrated in FIG. 5A, the insulator material 316 is deposited on the tops of the conductive interconnects 304 (e.g., on the conductive fill material 308 of the conductive interconnects 304), on exposed sides of the conductive interconnects 304 (e.g., on the liner 309 at the sides of the conductive interconnects 304), and on exposed portions of the insulator material 306 between adjacent conductive interconnects 304. In some examples, the thickness of the conformal layer of the insulator material 316 may depend on whether air gaps are to be formed. In the example illustrated in FIG. 5A (in which air gaps are not to be formed), the thickness on the sidewalls may be in a range of about 2 nanometers to about ¼ of the distance between two adjacent conductive interconnects 304. The thickness of the insulator material 316 over the tops of the conductive interconnects may be the same or different than the thickness on the sidewalls (e.g., due to first depositing the conformal layer of the insulator material 316 and then polishing the insulator material 316 at the top to reduce the thickness. In one example, the thickness of the insulator material 316 over the tops of the conductive interconnects may be in a range of about 2 to 20 nanometers.

Any suitable deposition technique may be used to deposit the conformal layer of the insulator material 316 in the process 206, e.g., any suitable conformal deposition technique where the insulator material 316 is provided with a substantially same thickness on all exposed surfaces. Examples of deposition techniques that may be used in the process 206 include atomic layer deposition (ALD), chemical vapor deposition (CVD), plasma enhanced CVD (PECVD), or/and physical vapor deposition (PVD) processes such as sputter. The insulator material 316 may be any suitable insulator material, such as an insulator material including oxygen and/or nitrogen (e.g., silicon nitride, silicon oxide, silicon oxynitride, etc.). The insulator material 316 may have a different material composition from the insulator material 306, or may have substantially the same material composition as the insulator material 306.

As can be seen in FIG. 5A, after deposition of the insulator material 316, there are still openings 310 between adjacent insulator material 306. In other words, portions of the insulator material 316 over adjacent conductive interconnects 304 have not merged to close off the tops of the openings 310). The openings 310 remain open at the top due to one or more features of the conductive interconnects 304 and/or the layer of the insulator material 316. For example, the taper and/or pitch of the conductive interconnects 304 may be such that the portions of layer of the insulator material 316 deposited over the conductive interconnects 304 do not meet at the top to close of the openings 310. The thickness of the layer of insulator material 316 may also impact whether the upper portions of the insulator material 316 meet to close off the openings 310.

FIG. 5B illustrates an example in which the shape and/or pitch of the conductive interconnects 304 and the thickness of the insulator material 316 result in voids or air gaps 320 between adjacent conductive interconnects 304. As can be seen in FIG. 5B, portions of the insulator material 316 on the upper sides of the conductive interconnects 304 meet and merge together, preventing further deposition of the insulator material 316 into the openings 310. In the example illustrated in FIG. 5B (in which air gaps are to be formed), the thickness on the sidewalls may at least ½ of the distance between two adjacent conductive interconnects 304. The thickness of the insulator material 316 over the top of the conductive interconnects may be the same or different than the thickness on the sidewalls (e.g., due to first depositing the conformal layer of the insulator material 316 and then polishing the insulator material 316 at the top to reduce the thickness. In one example, the thickness of the insulator material 316 over the tops of the conductive interconnects may be in a range of about 2 to 20 nanometers. The air gaps 320 may include minimal or no material (e.g., the air gaps 320 may be a vacuum or substantially a vacuum), or the air gaps 320 may be filled with a gaseous substance, e.g., nitrogen gas or a different gas. In the example illustrated in FIG. 5B, the air gaps 320 may be surrounded by the insulator material 316. For example, in a cross-section along a plane orthogonal to the substrate and orthogonal to the length of metal lines in the layer (e.g., in the x-z plane as shown in FIG. 5B), the air gaps 320 may be surrounded by the insulator material 316. Air gaps, where present in a metal layer, generally extend in parallel to metal lines. For example, in the interconnect layer 302 shown in FIG. 5B, air gaps 320 may extend in the y-direction between adjacent metal lines (which also extend in the y-direction), where the y-axis is going into and coming out of the page in FIG. 5B.

The location of the air gaps 320 between adjacent conductive interconnects 304 may vary, and in some examples, the air gaps 320 may be closer to the bottom of the conductive interconnects 304 than to the top of the conductive interconnects 304 (e.g., the air gaps 320 may be closer to the tapered ends of the conductive interconnects 304 than to the wider tops of the conductive interconnects 304). A cross-sectional shape of an air gap 320 may depend on implementation. In some examples, a cross-section of the air gaps 320 may have a substantially oval shape. In one example, the air gaps 320 may be wider at one end. For example, if the adjacent conductive interconnects 304 have a tapered shape with a narrower bottom end and a wider top end, then the portion of the air gaps 320 closest to the narrower bottom end of the conductive interconnects 304 may be wider than the portion of the air gaps closest to the wider top end of the conductive interconnects 304. In one such example, a cross-section of the air gaps 320 may have a shape that resembles an oval with one end that is wider. Thus, in some examples, the air gaps may have a variety of shapes, sizes, and locations between adjacent conductive interconnects 304 depending on a number of factors, such as the shape and pitch of the conductive interconnects 304 and the thickness of the insulator material 316.

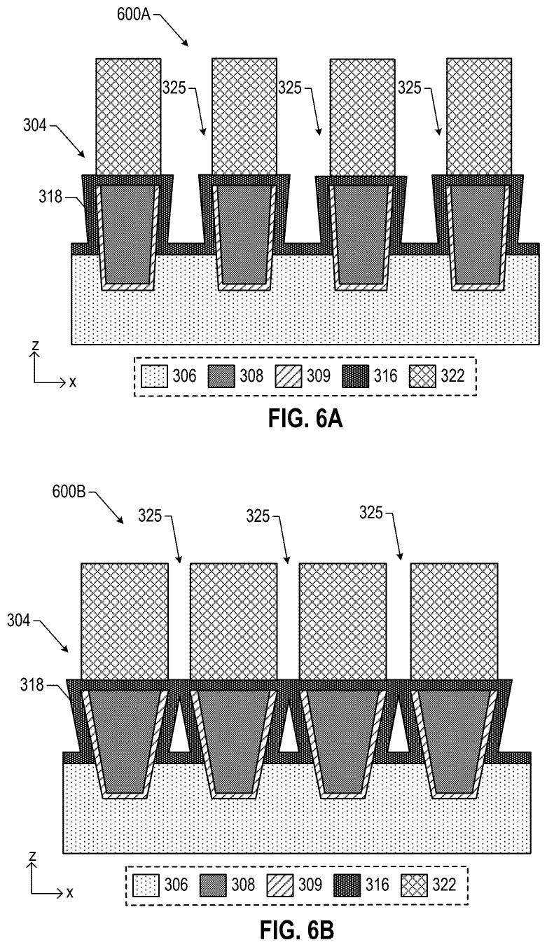

Referring again to FIG. 2, the method 200 involves the process 208 of selectively depositing a further material over the first conductive material. The IC structures 600A and 600B of FIGS. 6A and 6B are example resulting structures of the process 208. Specifically, the IC structure 600A is an example of the IC structure 500A after the process 208, and the IC structure 600B is an example of the IC structure 500B after the process 208. As can be seen in FIGS. 6A and 6B, the further material 322 is deposited only (e.g., substantially only) on the portions of the insulator material 316 over the conductive fill material 308. According to examples, the further material 322 is selected based on the material composition of the conductive fill material 308. Depending on the material composition of the conductive fill material 308, the conductive fill material 308 may have a propensity to attract particles of certain other materials (e.g., due to the relative electrostatic potential or the work functions of the conductive fill material 308 and the further material 322). For example, the conductive fill material 308 and the further material 322 may have opposite electrostatic potentials or polarities, so that the further material 322 is attracted to the conductive fill material 308 and is therefore selectively deposited over the conductive fill material 308, and not deposited over other areas (e.g., not over regions of the insulator material 306 between the conductive interconnects 304. Thus, the thickness of the insulator material 316 over the conductive fill material 308 may be sufficiently small so that the effects of the electrostatic potential of the conductive fill material 308 are felt beyond the insulator material 316 on the top surface of the conductive fill material 308.

In one example, if the conductive fill material 308 is copper, in some examples the further material 322 may be or include a metal, where the metal atoms or molecules are attracted to the copper, and therefore attach to portions of the insulator material 316 that are directly over the copper. In an example in which the conductive fill material 308 is tungsten, the further material 322 may be a material that includes oxygen (e.g., silicon oxide), where the oxygen ions are attracted to the tungsten, and therefore attach to portions of the insulator material that are directly over the tungsten. The thickness of the further material 322 may depend on the desired height of the resulting structure. Thus, the IC structure includes regions of the further material 322 directly over and aligned with the conductive fill material 308, and openings 325 between adjacent portions of the further material 322 (where the openings 325 are directly over and aligned with the regions between adjacent conductive interconnects 304).

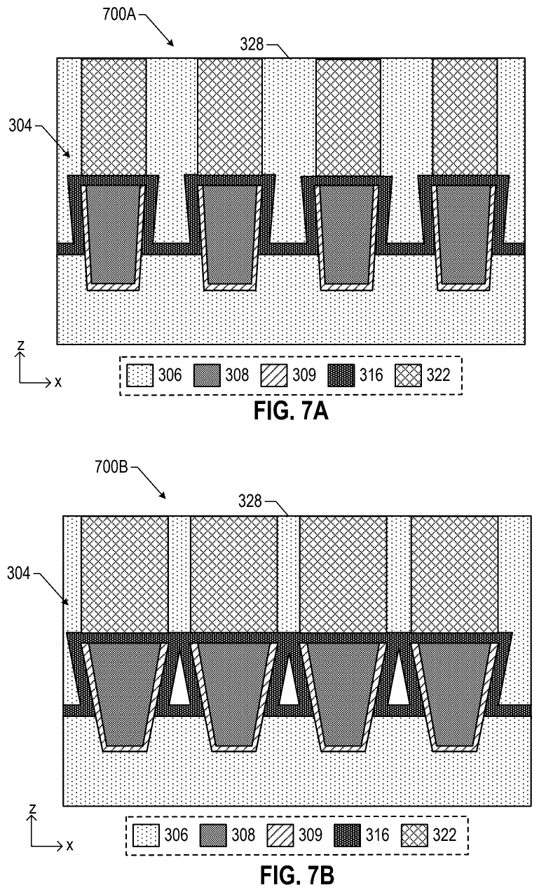

The method 200 continues with the process 210 of providing a third insulator material over the further material. The IC structures 700A and 700B of FIGS. 7A and 7B are example resulting structures of the process 210. Specifically, the IC structure 700A is an example of the IC structure 600A after the process 210, and the IC structure 700B is an example of the IC structure 600B after the process 210. As can be seen in FIGS. 7A and 7B, the insulator material 328 is deposited over the IC structure 700B so that it fills the openings 325 between adjacent regions of the further material 322. Although the insulator material 328 is shown with the same shading as the insulator material 306 the insulator material 328 may have a different material composition or substantially the same material composition as the insulator material 306. The insulator material 328 may be deposited with any suitable deposition technique may be deposited using any suitable deposition technique, such as ALD, CVD, PECVD, or a PVD processes such as sputter.

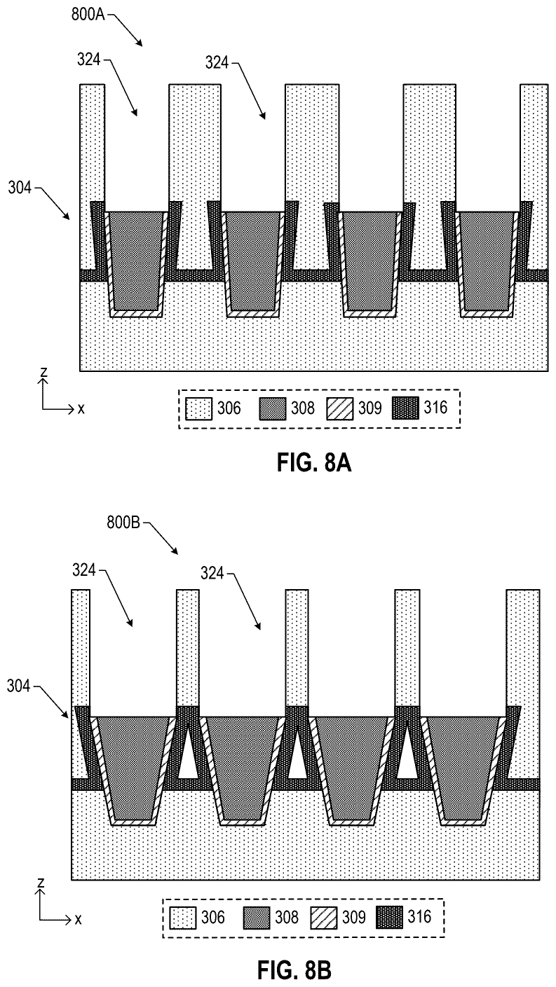

The method 200 continues with the process 212 of removing the further material to expose the first conductive material. The IC structures 800A and 800B of FIGS. 8A and 8B are example resulting structures of the process 212. Specifically, the IC structure 800A is an example of the IC structure 700A after the process 212, and the IC structure 800B is an example of the IC structure 700B after the process 212. As can be seen in FIGS. 8A and 8B, the further material 322 as well as the portions of the insulator material 316 on the tops of the conductive fill material 308 have been removed, revealing the conductive fill material 308 at the tops of the conductive interconnects 304. The further material 322 and the portions of the insulator material 316 may be removed with any suitable etching technique, e.g., a dry etch, such as e.g., radio frequency (RF) reactive ion etch (RIE) or inductively coupled plasma (ICP) RIE may be used to remove the further material 322 and the portions of the insulator material 316 from over the tops of the conductive fill material 308. After removing the further material 322 and the portions of the insulator material 316 from over the conductive fill material 308, the IC structures 800A, 800B include openings 324 that are directly over and aligned with the conductive interconnects 304.

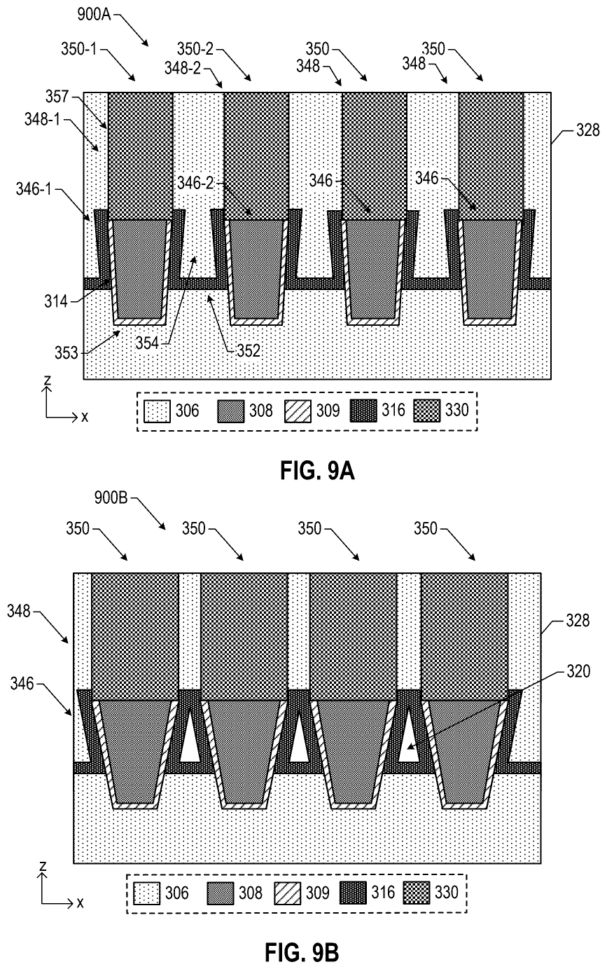

The method 200 continues with the process 214 of providing a second conductive material over the first conductive material. The IC structures 900A and 900B of FIGS. 9A and 9B are example resulting structures of the process 214. Specifically, the IC structure 900A is an example of the IC structure 800A after the process 214, and the IC structure 900B is an example of the IC structure 800B after the process 214. As can be seen in FIGS. 9A and 9B, the openings 324 resulting from removing the further material 322 are filled with a second conductive material 330. In the example illustrated in FIGS. 9A, 9B, the second conductive material 330 is directly on the conductive fill material 308 (e.g., in direct contact without an intervening material). The second conductive material 330 may have substantially the same material composition as the conductive fill material 308, or the 330 may have a different material composition from the conductive fill material 308. In some examples, the conductive fill material 308 may be selected for properties that provide a good contact with a first conductive element (e.g., in a layer under the interconnect layer 302), and the second conductive material 330 may be selected for properties that provide a good contact with a second conductive element (e.g., in a layer over the interconnect layer 302).

The second conductive material 330 over a conductive interconnect is aligned with the conductive fill material 308, forming conductive interconnects 350. In the example illustrated in FIGS. 9A, 9B, each of the conductive interconnects 350 includes a first portion 346 of the conductive fill material 308 (e.g., the original conductive interconnect 304) and a second portion 348 of the second conductive material 330 that is directly over and aligned with the first portion 346. Two of the conductive interconnects 350 in FIG. 9A (i.e., the conductive interconnects 350-1 and 350-2) are labeled with the numbers “350-1” and “350-2” in order to more clearly explain some examples below, while the other conductive interconnects are 350 are simply labeled “350.” In an example in which the conductive fill material 308 and the second conductive material 330 are different conductive materials, a conductive interconnect 350 may include an interface between the conductive fill material 308 and the second conductive material 330. Where the conductive fill material 308 and the second conductive material 330 have substantially the same material composition, an interface may or may not be visible in the resulting conductive interconnects 350.

Thus, FIG. 2 illustrates a method 200 for fabricating an IC structure including devices fabricated with pattern replication techniques using selective deposition. Performing the method 200 may result in several features in the final IC structures that are characteristic of the use of the method 200. For example, one such feature is illustrated in an IC structures 900A, 900B shown in FIGS. 9A, 9B, which show conductive interconnects 350, where a conductive interconnect 350 includes a first portion 346 including a first conductive fill material 308 in an opening (e.g., the opening in the insulator material 306 in which the conductive fill material 308 was deposited), and a second portion 348 over and aligned with the first portion 346, where the second portion 348 includes a second conductive fill material 330. As a result of the pattern replication process, a liner 309 may be present on sidewalls 314 of the conductive interconnect, and absent on sidewalls 357 of the opening of the second portion 348 (e.g., the liner 309 is limited to the first portion 346).

Additionally, the conformal layer of the insulator material 316 may be present in some regions of the final IC structure. For example, referring to FIGS. 9A-9B, the insulator material 316 may be present over at least a portion of the liner 309 on the sidewalls 314 of the conductive interconnect (e.g., the first portion 346 of the conductive interconnect). For example, in FIGS. 9A, and 9B, the first portion 346 is surrounded by a first insulator material 306, and a second insulator material 316 is between the first insulator material 306 and at least a portion of the liner 309 on the sidewalls of conductive interconnects 350 (e.g., the liner 309 on sidewalls 314 of the first portion 346 of the conductive interconnect 350 is between the conductive fill material 308 and the insulator material 316). Viewed another way, in the illustrated example, the insulator material 316 is present between the first portions of adjacent conductive interconnects. For example, referring to FIG. 9A, a first conductive interconnect 350-1 includes a first portion 346-1 including the conductive fill material 308 and a second portion 348-1 including the second conductive material 330 over and aligned with the first portion 346-1, and a second conductive 350-2 includes a third portion 346-2 including the conductive fill material 308 and a fourth portion 348-2 including the second conductive material 330 over and aligned with the third portion 346-2. In one such example, the insulator material 316 may be present between the first portion 346-1 and the third portion 346-2 (e.g., in the region 352 between the 350-1 and the 350-2 in a plane between the second portion 348-1 and the bottom 353 of the first portion 346-1, where the plane is substantially parallel with the substrate).

Also, as can be seen in FIGS. 9A and 9B, the conformal layer of the insulator material 316 is present over at least part of the liner 309 on the sidewalls 314 of the openings, but absent from over the liner at the bottom 353 of the openings. For example, the liner 309 may be present at a bottom 353 of an opening in which the conductive fill material 308 is deposited (e.g., the liner 309 may be between the conductive fill material 308 and another conductive element in a layer below the layer 302 (not shown in FIGS. 9A and 9B), or between the conductive fill material 308 and the insulator material 306 (as shown in FIGS. 9A and 9B). In one such example, the second insulator material 316 is absent from between the first insulator material 306 and the liner 309 at the bottom 353 of the opening (e.g., the second insulator material 316 is absent from between the first insulator material 306 and the liner 309 at a bottom portion of the second portion).

An IC structure fabricated with the method 200 may also include air gaps between adjacent conductive interconnects. In the example illustrated in FIG. 9B, the interconnect layer 302 may include air gaps 320 in the insulator material 316 between lower portions of the conductive interconnects 350. In some examples, the air gaps 320 may be present in a plane or layer with the first portions 346, and absent in a plane or layer with the second portions 348. In another example, the method 200 may be repeated to form third portions over and aligned with the second portions 348. For example, the method may further involve recessing the insulator material 328 to expose sides of the second conductive material 330, providing a conformal layer of the second insulator material 316 over the exposed top and sides of the second conductive material 330, selectively depositing the further material 322 over the second conductive material 330, providing the insulator material 328 over the further material 322, removing the further material 322 to expose the second conductive material 330, and providing a third conductive material over the second conductive material. In one such example, the third conductive material may have the substantially the same as one or both of the conductive fill material 308 and the second conductive material 330, or may have a different material composition from the conductive fill material 308 and/or the second conductive material 330. In one such example, air gaps may be present between adjacent second portions 348 of adjacent conductive interconnects. In the example illustrated in FIG. 9A in which the IC structure 900A does not have air gaps between adjacent conductive interconnects 350, a portion of the insulator material 328 may be present between adjacent portions of the insulator material 316 (e.g., such as in the region 354 between the portions 346-1 and 346-2 of FIG. 9A).

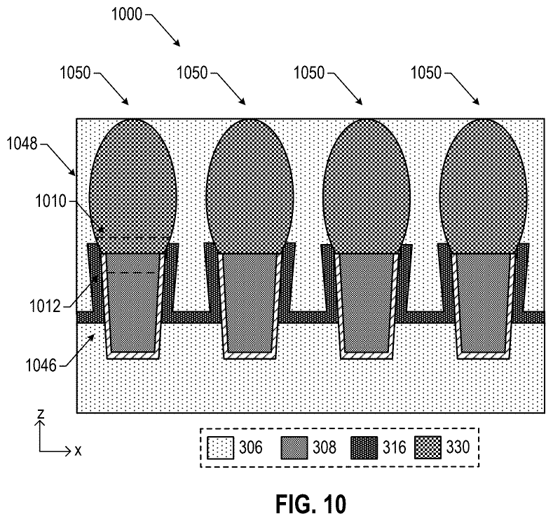

In some examples, an IC structure fabricated with the method 200 may have a conductive interconnect with a first and second portion in accordance with examples discussed above, where the second portion has a curved convex shape. FIG. 10 illustrates a cross-sectional view of an example IC structure 1000 in which the second portion of the conductive interconnect has a curved shape. As can be seen in FIG. 10, the IC structure 1000 includes conductive interconnects 1050, where each of the conductive interconnects 1050 includes a first portion 1046 including a first conductive material 308 and a second portion 1048 over the first portion 1046, where the second portion includes a second conductive material 330. Unlike the examples shown in FIGS. 9A and 9B, in the example illustrated in FIG. 10, a cross-section of the second portion 1048 (e.g., a cross-section of the second conductive material 330 of the second portion 1048) has a curved convex shape. In the example illustrated in FIG. 10, the second portion 1048 may have a larger width than the first portion 1046. For example, the first portion 1046 has a width (an example first width is indicated with a dotted line) at an end 1012 closest to the second portion 1048, the second portion 1048 has a second width (an example second width is indicated with a dotted line) at an end 1010 closest to the first portion 1046, where the second width is larger than the first width. Thus, the second portion of the conductive interconnects may have a substantially straight profile, or other shape, such as the curved profile shown in FIG. 10.

IC devices/structures fabricated with pattern replication techniques using selective deposition as described herein (e.g., as described with reference to FIGS. 1-4, 5A-5B, 6A-6B, 7A-7B, 8A-8B, 9A-9B, and 10) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

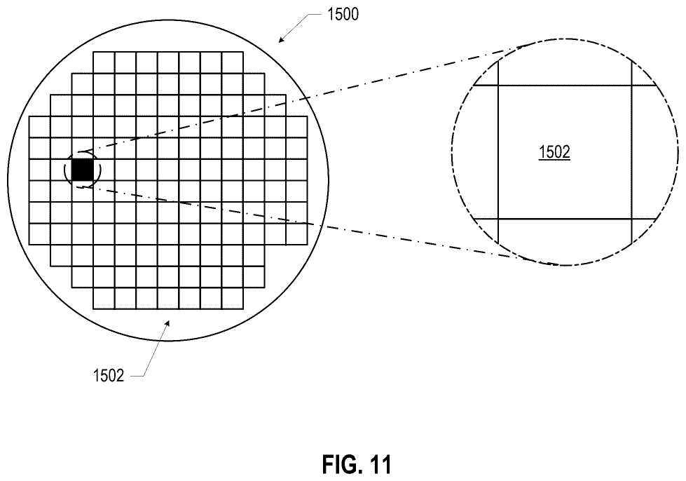

The IC devices/structures disclosed herein, e.g., the IC structures 900A, 900B, and 1000, or any variations thereof, may be included in any suitable electronic component. FIGS. 11-14 illustrate various examples of apparatuses that may include any of the IC devices disclosed herein.

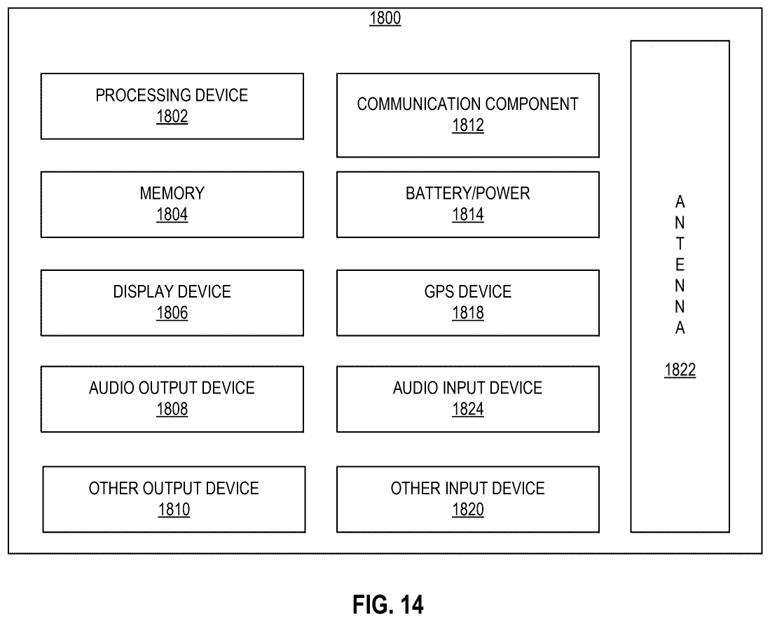

FIG. 11 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 900A, 900B, and 1000, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

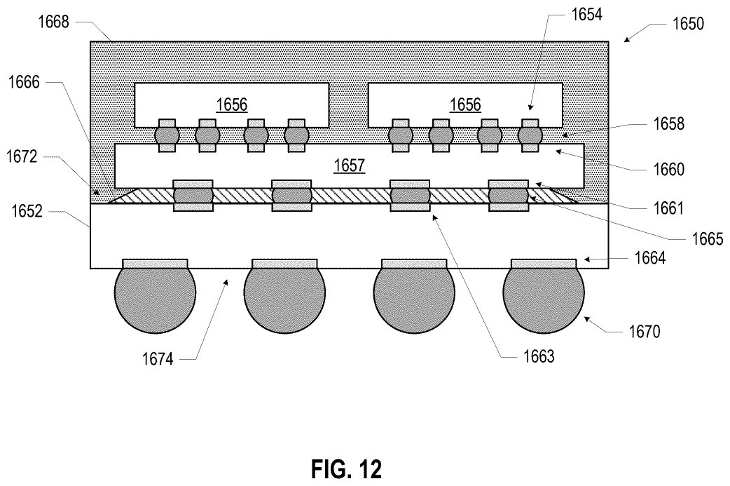

FIG. 12 is a side, cross-sectional view of an example IC package 1650 that may include one or more IC structures in accordance with any of the embodiments disclosed herein (e.g., any of the IC structures 900A, 900B, and 1000, or any variations thereof described herein, or any combination of such IC structures). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

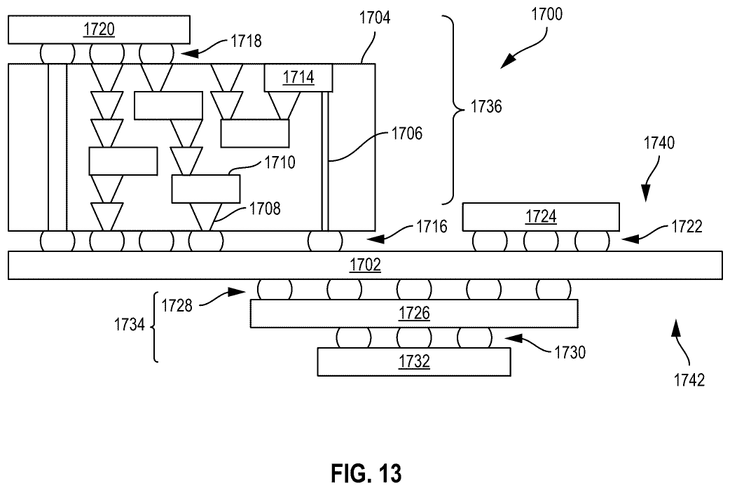

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 13.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 12 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 13 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more of the IC structures 900A, 900B, and 1000, or any variations thereof described herein, or any combination of such IC structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device (e.g., any of the IC structures 900A, 900B, and 1000, or any variations thereof described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a device region; and an interconnect layer over the device region, where the interconnect layer includes a conductive interconnect, where the conductive interconnect (e.g., via or metal line) includes a first portion including a first conductive material (e.g., a first conductive fill material in an opening), and a second portion over and aligned with the first portion, where the second portion includes a second conductive material (e.g., a second conductive fill material), a liner on sidewalls of the conductive interconnect, wherein the liner is limited to the first portion.

Example 2 provides the IC structure of example 1, where: the liner includes a metal (e.g., TaN, Ta, TiN, Ti).

Example 3 provides the IC structure of examples 1 or 2, where: the first portion is surrounded by a first insulator material, and the interconnect layer further includes a second insulator material between the first insulator material and at least a portion of the liner on the sidewalls (e.g., the opening is in a first insulator material, and the interconnect layer further includes a second insulator material over at least a portion of the liner on the sidewalls).

Example 4 provides the IC structure of example 3, where: the second insulator material is absent from between the first insulator material and the liner at a bottom portion of the first portion (e.g., the liner is at a bottom of the opening, and the second insulator material is absent from between the first insulator material and the liner at the bottom of the opening).

Example 5 provides the IC structure of examples 3 or 4, where: the conductive interconnect is a first conductive interconnect, the interconnect layer further includes a second conductive interconnect adjacent to and coplanar with the first conductive interconnect, where the second conductive interconnect includes a third portion including the first conductive material (e.g., in a second opening in the first insulator material), and a fourth portion over and aligned with the third portion, where the fourth portion includes the second conductive material, and the second insulator material is present between the first portion and the third portion.

Example 6 provides the IC structure of example 5, where: the interconnect layer further includes an air gap in the second insulator material between the first portion and the third portion.

Example 7 provides the IC structure of any one of examples 1-6, where: a cross-section of the second portion has a curved convex shape.

Example 8 provides the IC structure of any one of examples 1-7, where: the first conductive material has a different material composition from the second conductive material.

Example 9 provides the IC structure of any one of examples 1-7, where: the first conductive material has a substantially same material composition as the second conductive material.

Example 10 provides the IC structure of any one of examples 1-9, where: the first portion has a first width at an end closest to the second portion, the second portion has a second width at an end closest to the first portion, and the second width is larger than the first width.

Example 11 provides the IC structure of any one of examples 1-10, where: the first conductive material has a first thickness, the second conductive material has a second thickness, where the first thickness and the second thickness are dimensions in a plane substantially orthogonal to the device region, and a ratio of the first thickness to the second thickness is in a range of 5:1 to 1:2.

Example 12 provides the IC structure of any one of examples 1-11, where: conductive interconnect includes a third portion over and aligned with the second portion.

Example 13 provides the IC structure of example 12, where: the interconnect layer further includes an air gap between the third portion and a corresponding portion of an adjacent conductive interconnect.

Example 14 provides an IC structure, including a device region; and a metallization stack over the device region, where at least one layer of the metallization stack includes a plurality of coplanar conductive interconnects, where a conductive interconnect of the coplanar conductive interconnects includes a first portion including a first conductive material, and a second portion over the first portion, where the second portion includes a second conductive material, and where: the liner is present on first sidewalls and a bottom of the first portion, and the liner is absent from second sidewalls of the second portion.

Example 15 provides the IC structure of example 14, where: the liner includes a third conductive material including a metal.

Example 16 provides the IC structure of example 14, where: the conductive interconnect is in an opening in a first insulator material, and a second insulator material is present over at least a portion of the liner on the first sidewalls.

Example 17 provides the IC structure of example 16, where: the second insulator material is present between the first portion and a coplanar portion of an adjacent conductive interconnect.

Example 18 provides the IC structure of example 17, where: an air gap is present between the first portion and the coplanar portion of the adjacent conductive interconnect, where the air gap is surrounded by the second insulator material in a cross-section in a plane substantially orthogonal to the device region that cuts through the conductive interconnect and the adjacent conductive interconnect.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a preliminary IC structure including an interconnect layer with a conductive interconnect surrounded by a first insulator material, where the conductive interconnect includes a first conductive material; recessing the first insulator material to expose a top and sides of the conductive interconnect; providing a (thin) conformal layer of a second insulator material over the exposed top and sides of the conductive interconnect; selectively depositing a further material (e.g., a conductive material) over the first conductive material; providing a third insulator material over the further material; removing the further material to expose the first conductive material; and providing a second conductive material over the first conductive material.

Example 36 provides the method of example 35, where: the first conducive material includes copper, and the further material includes a metal.

Example 37 provides the method of examples 35 or 36, where: the first conductive material has a different material composition from the second conductive material.

Example 38 provides the method of any one of examples 35-37, further including recessing the third insulator material to expose sides of the second conductive material; providing a conformal layer of the second insulator material over the exposed top and sides of the second conductive material; selectively depositing the further material over the second conductive material; providing the third insulator material over the further material; removing the further material to expose the second conductive material; and providing a third conductive material over the second conductive material.

Example 39 provides a method according to any one of examples 35-38, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a device region; and
an interconnect layer over the device region, wherein the interconnect layer includes:
a conductive interconnect, wherein the conductive interconnect includes:
a first portion including a first conductive material, and
a second portion over and aligned with the first portion, wherein the second portion includes a second conductive material, and
a liner on sidewalls of the conductive interconnect, wherein the liner is limited to the first portion.

2. The IC structure of claim 1, wherein:
the liner includes a metal.

3. The IC structure of claim 1, wherein:
the first portion is surrounded by a first insulator material, and the interconnect layer further includes a second insulator material between the first insulator material and at least a portion of the liner on the sidewalls.

4. The IC structure of claim 3, wherein:
the second insulator material is absent from between the first insulator material and the liner at a bottom portion of the first portion.

5. The IC structure of claim 3, wherein:
the conductive interconnect is a first conductive interconnect,
the interconnect layer further includes:
a second conductive interconnect adjacent to and coplanar with the first conductive interconnect, wherein the second conductive interconnect includes:
a third portion including the first conductive material, and
a fourth portion over and aligned with the third portion, wherein the fourth portion includes the second conductive material, and
the second insulator material is present between the first portion and the third portion.

6. The IC structure of claim 5, wherein:
the interconnect layer further includes an air gap in the second insulator material between the first portion and the third portion.

7. The IC structure of claim 1, wherein:
a cross-section of the second portion has a curved convex shape.

8. The IC structure of claim 1, wherein:
the first conductive material has a different material composition from the second conductive material.

9. The IC structure of claim 1, wherein:
the first conductive material has a substantially same material composition as the second conductive material.

10. The IC structure of claim 1, wherein:
the first portion has a first width at an end closest to the second portion, the second portion has a second width at an end closest to the first portion, and the second width is larger than the first width.

11. The IC structure of claim 1, wherein:
the first conductive material has a first thickness,
the second conductive material has a second thickness, wherein the first thickness and the second thickness are dimensions in a plane substantially orthogonal to the device region, and
a ratio of the first thickness to the second thickness is in a range of 5:1 to 1:2.

12. The IC structure of claim 1, wherein:
conductive interconnect includes a third portion over and aligned with the second portion.

13. The IC structure of claim 12, wherein:
the interconnect layer further includes an air gap between the third portion and a corresponding portion of an adjacent conductive interconnect.

14. An integrated circuit (IC) structure, comprising:
a device region; and
a metallization stack over the device region, wherein at least one layer of the metallization stack includes a plurality of coplanar conductive interconnects, wherein a conductive interconnect of the coplanar conductive interconnects includes:
a first portion including a first conductive material, and a second portion over the first portion, wherein the second portion includes a second conductive material, and wherein:
a liner is present on first sidewalls and a bottom of the first portion, and
the liner is absent from second sidewalls of the second portion.

15. The IC structure of claim 14, wherein:
the liner includes a third conductive material including a metal.

16. The IC structure of claim 14, wherein:
the conductive interconnect is in an opening in a first insulator material, and a second insulator material is present over at least a portion of the liner on the first sidewalls.

17. The IC structure of claim 16, wherein:
the second insulator material is present between the first portion and a coplanar portion of an adjacent conductive interconnect.

18. The IC structure of claim 17, wherein:
an air gap is present between the first portion and the coplanar portion of the adjacent conductive interconnect, wherein the air gap is surrounded by the second insulator material in a cross-section in a plane substantially orthogonal to the device region that cuts through the conductive interconnect and the adjacent conductive interconnect.

19. A method of fabricating an integrated circuit (IC) structure, the method comprising:
providing a preliminary IC structure including an interconnect layer with a conductive interconnect surrounded by a first insulator material, wherein the conductive interconnect includes a first conductive material;
recessing the first insulator material to expose a top and sides of the conductive interconnect;
providing a conformal layer of a second insulator material over the exposed top and sides of the conductive interconnect;
selectively depositing a further material over the first conductive material;
providing a third insulator material over the further material;
removing the further material to expose the first conductive material; and
providing a second conductive material over the first conductive material.

20. The method of claim 19, wherein:
the first conductive material comprises copper, and the further material comprises a metal.
